(19) United States
(12) Patent Application Publication
(10) Pub. No.: US 2026/0362996 A1
(43) Pub. Date: Nov. 12, 2026

(54) METHODS FOR MAKING SOLID STATE DEVICES HAVING SPIN-PHOTON INTERFACES

(71) Applicant: PHOTONIC INC., Coquitlam (CA)

(72) Inventors: Mohsen KESHAVARZ AKHLAGHI, North Vancouver (CA); Navid Mohammad Sadeghi JAHED, Kitchener (CA)

(21) Appl. No.: 19/135,975

(22) PCT Filed: Dec. 5, 2023
(86) PCT No.: PCT/CA2023/051611

§ 371 Date: Jun. 5, 2025

Related U.S. Application Data
(60) Provisional application No. 63/387,534, filed on Dec. 15, 2022.

(51) Int. Cl. H10P 32/14; G06N 10/40; H10P 14/20; H10P 95/90

(52) U.S. Cl. CPC H10P 32/14; G06N 10/40; H10P 14/3206; H10P 14/3411; H10P 95/90

(57) ABSTRACT

A method for forming luminescent centres (e.g. T centres) on silicon substrates, the method comprising providing a substrate (e.g. silicon on insulator substrate); forming a device layer on the substrate by providing or forming a first silicon layer, forming an interfacial layer on the first silicon layer by delta doping of carbon atoms, and forming a second silicon layer on the interfacial layer; applying a first annealing process to the device layer to distribute carbon atoms within the device layer; introduce hydrogen atoms into the device layer; and applying a second annealing process to form luminescent centres within the device layer. In some embodiments, a superlattice structure is formed in the device layer with a plurality of alternating silicon layers and interfacial layers.

### CROSS-REFERENCE TO RELATED APPLICATIONS

This application claims priority from U.S. application No. 63/387,534 filed 15 Dec. 2022 and entitled METHODS FOR MAKING SOLID STATE DEVICES HAVING SPIN-PHOTON INTERFACES which is hereby incorporated herein by reference for all purposes. For purposes of the United States of America, this application claims the benefit under 35 U.S.C. § 119 of U.S. application No. 63/387,534 filed 15 Dec. 2022 and entitled METHODS FOR MAKING SOLID STATE DEVICES HAVING SPIN-PHOTON INTERFACES which is hereby incorporated herein by reference for all purposes.

### FIELD

This invention relates to generating spin-photon interfaces in silicon. Specific embodiments provide methods and apparatus for creating point defect colour centres such as T centres or G centres in silicon crystals.

### BACKGROUND

Quantum informatics involves storing and/or manipulating information represented by the state of a quantum system or a set of quantum systems. Quantum information may, for example be represented by the states of quantum systems as diverse as photons, superconducting loops, electron spins, nuclear spins, ions and others.

There are advantages in using quantum systems that are natively integrated into silicon and able to interact with light at telecommunication wavelengths for storing and manipulating quantum information.

Point defect colour centres have shown promise for use as quantum systems for storing and manipulating quantum information. Radiation damage centres in silicon are a class of point defect colour centres that shows promise for use as quantum systems for quantum informatics.

### SUMMARY

Within the family of radiation damage centres, the T centre notably possesses highly coherent electron and nuclear spin degrees of freedom as well as narrow, spin-dependent ensemble optical transitions that can emit and/or absorb photons at wavelengths of approximately 1326 nm, which lies in the telecommunications O-band. T centres can serve as long-lived colour centres.

A T centre is made up of two carbon atoms and a hydrogen atom which occupy a location in a silicon crystalline lattice where one silicon atom is missing. The two carbon atoms share the substitutional site of the missing silicon atom. The interstitial hydrogen atom is chemically bonded to one of the carbon atoms while the other carbon atom remains stable with an unpaired electron.

It has been demonstrated that a high concentration T centre ensemble can be fabricated in a silicon device layer of a silicon-on-insulator (SOI) wafer by ion implantation to introduce carbon and hydrogen ions into a silicon crystal and subsequent annealing of the silicon crystal. However, one drawback of this approach to creating T centres is that it is hard to control the depth in the silicon crystal at which the T centres are formed. In particular, the vertical distribution of T centres created by such ion implantation techniques is determined by implantation and annealing parameters, including implantation dose, acceleration voltage and annealing temperature. It would be beneficial to have finer control of the depth at which T centres are formed, for example, so that T centres can be placed at defined locations relative to other structures such as optical structures.

Another drawback of making T centres by ion implantation is that the ion implantation creates disorder/damages near the surface of the silicon due to the bombardment of the crystalline silicon with carbon atoms. Lattice disorder and crystal damage may degrade performance of T centres, for example by enhancement of trap states and recombination centres. Damage to the crystal lattice and formation of recombination centres inside the crystal lattice near the surface can lead to lower exciton lifetime and reduce coherence time of T centres. Qubit decoherence, relaxation from adsorbates on surfaces, impurities at interfaces, and material defects can all negatively impact performance of the T centres in quantum data processing applications.

Accordingly, systems of spin-photon interfaces and methods of fabricating spin-photon interfaces near ideal positions within the device layer of a wafer are desired.

This invention has a number of aspects. These include but are not limited to:
methods for making devices that include spin-photon interfaces. The spin-photon interfaces may, for example, comprise T centres or G centres.
precursor devices that include spin-photon interfaces; and
devices that include spin-photon interfaces and optical structures which facilitate optical interactions with the spin photon interfaces.

One example aspect of the invention provides a method for making a device that includes luminescent centres. The method comprises the steps of:
(a) fabricating a device layer on a substrate by:
   (i) forming, on a first silicon layer formed on the substrate, a first interfacial layer of a carbon containing material on the first silicon layer; and,
   (ii) forming a second silicon layer on the first interfacial layer;
(b) introducing hydrogen atoms into the device layer; and,
(c) annealing the device layer to cause the carbon atoms and the hydrogen atoms to form luminescent centres within the device layer.

In some embodiments the method may further comprise providing the substrate and forming the first silicon layer on the substrate. In some embodiments the annealing process is a second annealing process and the method comprises causing carbon atoms to diffuse into the first and second silicon layers from the first interfacial layer by applying a first annealing process after forming the second silicon layer. In some embodiments the first annealing process has an annealing temperature of at least 500 °C. In some embodiments the second annealing process includes processing at an annealing temperature of at least 400 °C.

In some embodiments the method comprises forming a plurality of alternating interfacial layers and silicon layers by alternately applying step (a)(i) to each successive silicon layer and step (a)(ii) to each successive interfacial layer before step (b). In some embodiments at least one of the silicon layers is formed through epitaxial growth or chemical vapor deposition.

In some embodiments at least one of the silicon layers comprises isotopically purified silicon-28.

In some embodiments the carbon containing material is elemental carbon. In some embodiments the carbon containing material is silicon carbide. In some embodiments the carbon containing material is isotopically enriched in ¹³C. In some embodiments the carbon containing material is isotopically enriched in ¹²C. In some embodiments the carbon containing material is a mixture of isotopically enriched ¹²C and ¹³C. In some embodiments the carbon containing material is carbon doped silicon. In some embodiments the carbon containing material contains isotopically purified silicon-28.

In some embodiments, a concentration of the luminescent centres is greatest at a depth corresponding to the interfacial layer.

In some embodiments at least the step or introducing hydrogen atoms into the device layer is performed in a high vacuum environment.

In some embodiments the first silicon layer has a thickness of less than 50 nm.

In some embodiments the first interfacial layer has a thickness of less than 5 nm. In some embodiments the first interfacial layer has a thickness of about 5 Angstroms.

In some embodiments the second silicon layer has a thickness in the range of about 10 nm to about 500 nm.

In some embodiments a thickness of the device layer is about 500 nm or less.

In some embodiments the first interfacial layer has a carbon concentration of at least 1×10¹⁸ atoms cm⁻³. In some embodiments the first interfacial layer has a carbon concentration of at least 1×10¹⁹ atoms cm⁻³.

In some embodiments the first interfacial layer has a carbon density in a range of about 1×10¹¹ atoms cm⁻² to about 1×10¹³ atoms cm⁻². In some embodiments the first interfacial layer has a carbon density in a range of about 1×10¹² atoms cm⁻² to about 1×10¹³ atoms cm⁻².

In some embodiments the method comprises forming an intermediate silicon layer on the first silicon layer prior to forming the first interfacial layer.

In some embodiments a thickness of the second silicon layer is at least equal to a combined thickness of the first silicon layer, the intermediate silicon layer and the first interfacial layer.

In some embodiments the substrate is a silicon on insulator (SOI) comprising an oxide insulator layer wherein the first silicon layer is formed on the oxide insulator layer.

In some embodiments the first silicon layer is a seed layer.

In some embodiments the silicon layers of the plurality of alternating interfacial layers and silicon layers each has a thickness of 20 nm or less.

Another example aspect of the invention provides a precursor device comprising:

a substrate comprising a carrier silicon layer and an insulator layer; a device layer supported on the substrate, the device layer comprising:
a first silicon layer adjacent to the insulator layer of the substrate;
an interfacial layer of carbon containing material deposited on the first silicon layer, the interfacial layer having a thickness not exceeding 2 nm; and
a second silicon layer deposited on the interfacial layer.

In some embodiments the precursor comprises a second interfacial layer of carbon containing material deposited on the second silicon layer and a third silicon layer deposited on the second interfacial layer.

In some embodiments the precursor comprises a third interfacial layer of carbon containing material deposited on the third silicon layer and a fourth silicon layer deposited on the third interfacial layer.

In some embodiments at least one of the silicon layers comprises isotopically purified silicon-28.

In some embodiments the carbon containing material is silicon carbide. In some embodiments the carbon containing material is carbon doped silicon. In some embodiments the carbon containing material is elemental carbon. In some embodiments the carbon containing material contains isotopically purified silicon-28. In some embodiments the carbon containing material is isotopically enriched in ¹³C. In some embodiments the carbon containing material is isotopically enriched in ¹²C.

In some embodiments the first silicon layer has a thickness of less than 50 nm.

In some embodiments the interfacial layer has a thickness of about 5 Angstrom.

In some embodiments the second silicon layer has a thickness in the range of about 10 nm to about 500 nm.

In some embodiments a thickness of the device layer is 500 nm or less.

In some embodiments the interfacial layer has a carbon concentration of at least 1×10¹⁸ atoms cm⁻³. In some embodiments the interfacial layer has a carbon concentration of at least 1×10¹⁹ atoms cm⁻³.

In some embodiments the interfacial layer has a density of about 1×10¹¹ atoms cm⁻² to about 1×10¹³ atoms cm⁻². In some embodiments the interfacial layer has a density of about 1×10¹² atoms cm⁻² to about 1×10¹³ atoms cm⁻².

In some embodiments the precursor device comprises an intermediate silicon layer between the first silicon layer and the interfacial layer.

In some embodiments a thickness of the second silicon layer is at least equal to a combined thickness of the first silicon layer, the intermediate silicon layer and the interfacial layer.

In some embodiments the substrate is a silicon on insulator (SOI) substrate.

Another example aspect of the invention provides a device comprising:
a substrate;
a device layer supported on the substrate, the device layer comprising crystalline silicon and having a thickness of 500 nm or less;
a plurality of luminescent centres localized within the device layer and concentrated within a first depth range that is equal to one half of the thickness of the device layer ±25%,
wherein an average concentration of the luminescent centres within the first depth range is at least five times greater than an average concentration of the luminescent centres in a second depth range that extends from an outer surface of the device layer by a distance equal to 10% of the thickness of the device layer.

In some embodiments the luminescent centres are T centres.

In some embodiments the device further comprises an optical layer on the device layer wherein the optical layer comprises a plurality of optical resonators which have resonances at wavelengths corresponding to optical transitions of the T centres.

Another aspect of the invention provides apparatus having any new and inventive feature, combination of features, or sub-combination of features as described herein.

Another aspect of the invention provides methods having any new and inventive steps, acts, combination of steps and/or acts or sub-combination of steps and/or acts as described herein.

Further aspects and example embodiments are illustrated in the accompanying drawings and/or described in the following description.

It is emphasized that the invention relates to all combinations of the above features, even if these are recited in different claims.

### BRIEF DESCRIPTION OF THE DRAWINGS

The accompanying drawings illustrate non-limiting example embodiments of the invention.

FIG. 1 is a model that shows the structure of a T centre.

FIG. 2 is a schematic cross sectional view of a SOI substrate.

FIG. 3 is a flowchart for an example method of generating spin-photon interface in substrates with doping according to an example embodiment.

FIG. 4A is a schematic cross sectional view of a substrate according to an example embodiment.

FIG. 4B is a schematic cross sectional view of a substrate according to another example embodiment.

FIG. 4C is a schematic cross sectional view of a substrate according to another example embodiment.

FIG. 5 schematically illustrates an example carbon concentration profile within a modified device layer in the example embodiment substrate shown in FIG. 2A.

FIG. 6 schematically illustrates another example carbon profile within another modified device layer in another example embodiment substrate.

### DETAILED DESCRIPTION

Throughout the following description, specific details are set forth in order to provide a more thorough understanding of the invention. However, the invention may be practiced without these particulars. In other instances, well known elements have not been shown or described in detail to avoid unnecessarily obscuring the invention. Accordingly, the specification and drawings are to be regarded in an illustrative, rather than a restrictive sense

This invention relates to creating spin-photon interfaces in silicon. A spin-photon interface is a structure which includes at least one particle that has intrinsic spin and a plurality of states wherein the states can exist in quantum superpositions, such that there exists at least one spin-dependent (optical) transition between the states. A spin photon interface may selectively absorb a photon having a wavelength corresponding to the spin-dependent transition depending on a spin eigenstate of the particle. A spin photon interface may be caused to selectively emit a photon having a wavelength corresponding to the spin-dependent transition depending on a spin state of the particle. A spin-photon interface may, for example be applied (i.e. put to practical use) to generate photons in states that correspond to or are entangled with a quantum state of the spin-photon interface; set a quantum state of the spin photon interface to a quantum state that corresponds to the state of a photon incident on the spin-photon interface; store quantum information in the states of the particle; and/or facilitate (optical) initialization and manipulation of the quantum state of the particle.

An example structure that may be used as a spin-photon interface is a T centre. Another example structure that may be used as a spin photon interface is a G centre.

For some applications, there is an advantage to having a spin-photon interface (e.g. a T centre) in the middle of a device layer (e.g. a device layer of a SOI wafer) where the crystalline defects are smaller, the distance to insulator and top interfaces are maximum, and the optical mode intensity is maximum. In addition, for some applications, there is advantage to creating T centres while minimizing creation of other crystalline defects.

One aspect of this invention provides methods for making structures that include silicon crystals that contain spin-photon interfaces such as T centres. Another aspect of this invention provides devices that include silicon crystals that contain spin-photon interfaces such as T centres. Another aspect of the invention provides devices that incorporate spin photon interfaces and have novel structures as described herein. Some embodiments provide devices that includes spin-photon interfaces such as T centres that are provided within a layer of silicon. The layer of silicon may be supported on a silicon on insulator (SOI) substrate. Spin photon interfaces may be distributed in the layer of silicon as described herein.

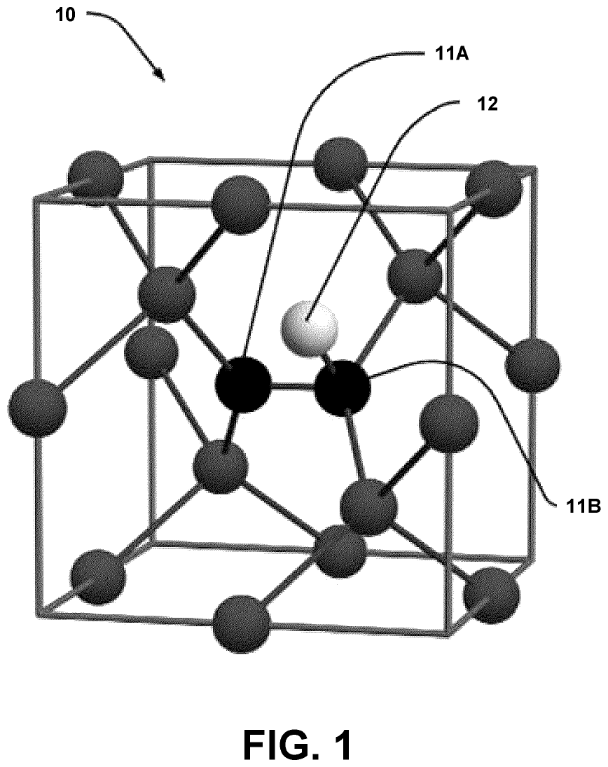

FIG. 1 is a model that shows the structure of a T centre 10. The T centre is a structure in which a silicon atom in a silicon crystal has been replaced by two carbon atoms 11A and 11B and a hydrogen atom 12 bonded to carbon atom 11B. Carbon atom 11A has one unpaired electron. The spin state of the unpaired electron of carbon atom 11A may be used as a quantum system. The nucleus of hydrogen atom 12 may also be used as a quantum system.

In some embodiments, one or both of the carbon atoms in a T centre are the carbon isotope ¹³C. Nuclei of carbon-13 atoms have a spin of ½ and may be used as additional quantum systems (by contrast, nuclei of the carbon isotope ¹²C do not have a net spin).

T centres have properties that make their spins particularly good for use as storing quantum information. These properties include:
T centres exhibit long spin coherence times (>2.1 ms electron and >1 s nuclear spin);
T centres have narrow optical linewidths (<30 MHz);
T centres can couple to O-band photons (wavelengths including about 1326 nm);
A T centre can provide multiple (e.g. up to 4) accessible spin manifolds;

1A T centre couples weakly but controllably to lattice strain;
A T centre couples weakly but controllably to electric fields;
A T centre can support excitons which may be used to store quantum information (e.g. in hole spins).

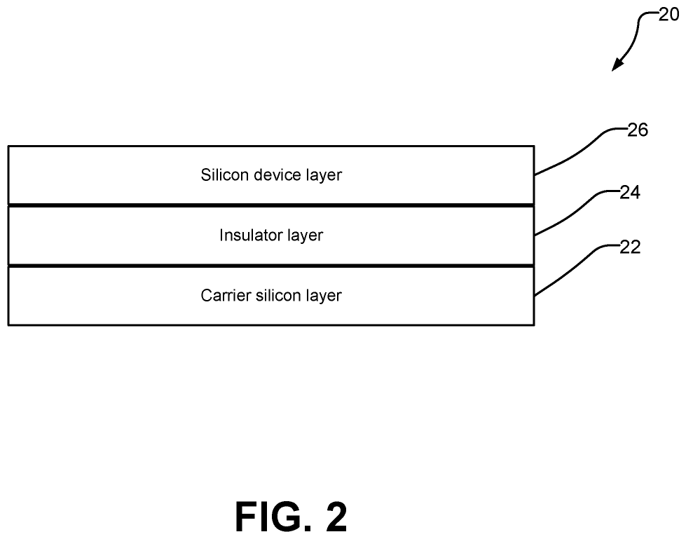

FIG. 2 is a schematic cross sectional view of a SOI substrate 20. SOI substrate 20 comprises a carrier silicon layer 22, an insulator layer 24 fabricated on carrier silicon layer 22, and a silicon device layer 26 fabricated on insulator layer 24 such that insulator layer 24 is sandwiched between carrier silicon layer 22 and silicon device layer 26. Insulator layer 24 typically comprises silicon dioxide. Insulator layer 24 may be made with buried oxide in which case insulator layer 24 is sometimes referred to as a BOX layer. SOI substrates make convenient substrates for supporting active components of devices. In some embodiments devices as described herein include SOI substrates. In some embodiments SOI substrate 20 includes other layers. For example, additional layers may be included between carrier silicon layer 22 and BOX layer 24 to provide a Bragg reflector.

The thickness of carrier silicon layer 22 is typically in the range of about 100 microns to about 1000 microns, the thickness of insulator layer 24 is typically in the range of about 500 nm to about 5000 nm, and the thickness of silicon device layer 26 is typically in the range of about 100 nm to 500 nm.

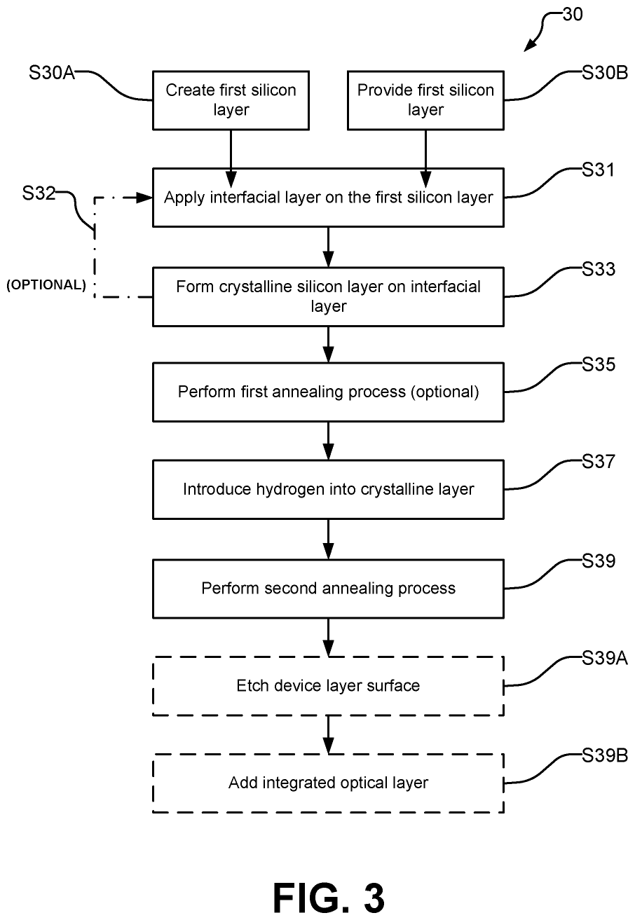

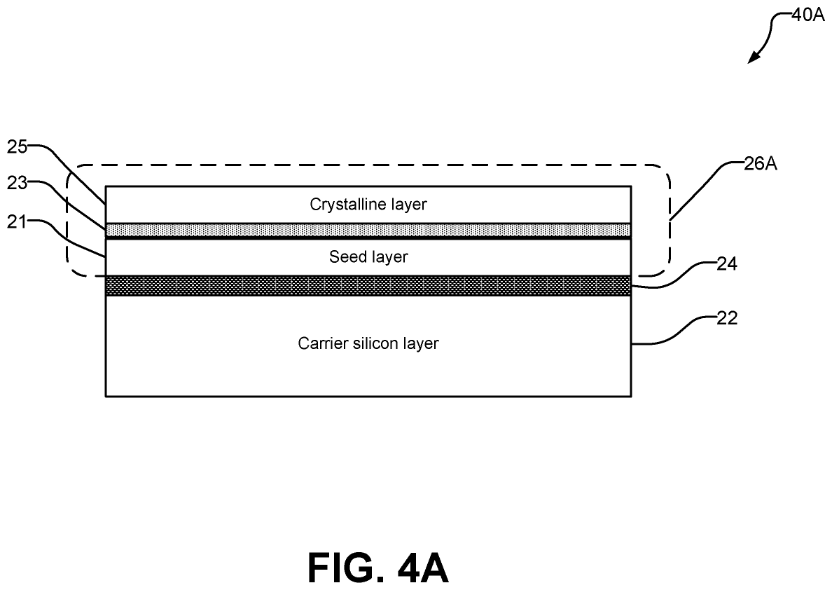

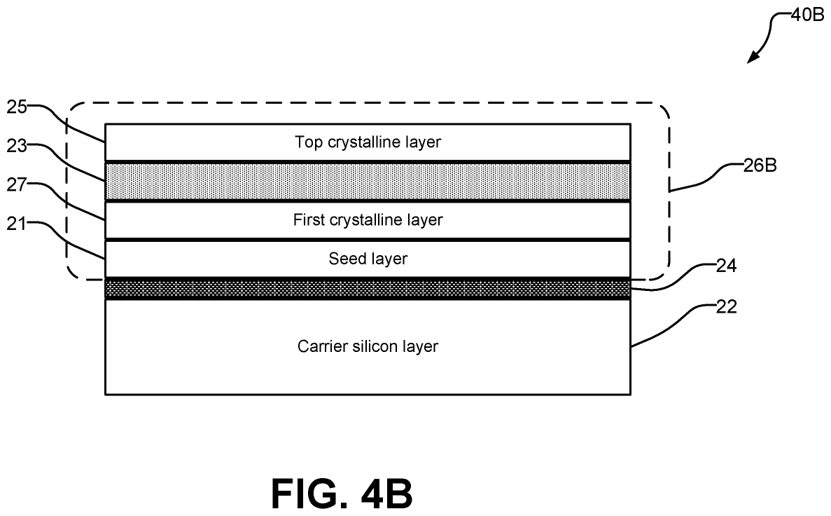

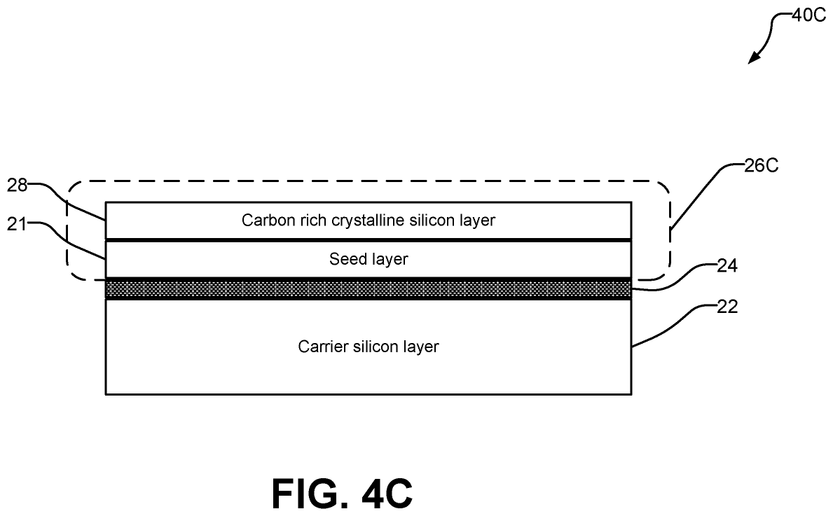

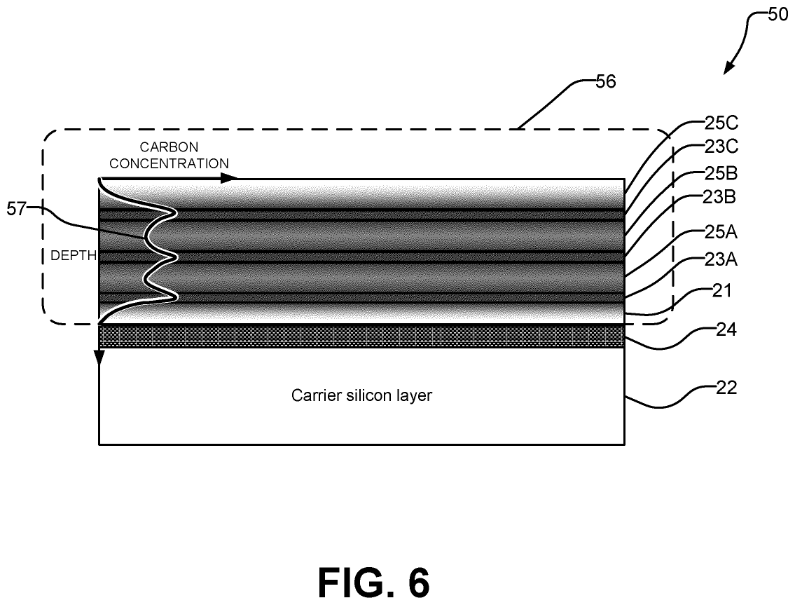

FIG. 3 is a flowchart for a method 30 of making a device that includes spin-photon interfaces. Method 30 involves creating a plurality of silicon layers with adjacent ones of the layers separated by thin layers of carbon (e.g. modified device layers 26A, 26B and 56 shown in FIG. 4A, FIG. 4B and FIG. 6 respectively). The resulting structure is annealed to cause carbon to diffuse into the silicon layers at a density which promotes formation of spin-photon interfaces such as luminescent centres and, in particular, luminescent centres in silicon that comprise carbon e.g. T centres or G centres in the silicon. Although some aspects of the following method are described with respect to making a device that includes T centres, it will be appreciated that such aspects may be adapted for making a device that includes other spin-photon interfaces, such as other luminescent centres and, in particular, other luminescent centres in silicon that comprise carbon. For example, to make a device that includes G centres, the method 30 may include one or more additional steps to form interstitial carbon or silicon. These steps may include, for example, silicon ion implantation, plasma doping (e.g. using reactive ion etching) etc.

At block S30A or S30B a first silicon layer is created or provided. The first layer of silicon may, for example comprise a seed layer 21 (see FIGS. 4A and 4B). A seed layer may serve as a catalyst layer that facilitates the growth of subsequent high quality functional layers of silicon by a process such as CVD or MBE and which establishes an orientation of one or more subsequent layers of silicon. Alternatively, the first layer of silicon might not be a seed layer. There are various insulators on which crystalline material may be grown without requiring a seed layer. One example of such an insulator is sapphire. Thus, for example, the first layer of silicon may comprise a layer of silicon grown on sapphire.

The first layer of silicon is preferably a thin layer. The first layer of silicon is preferably monocrystalline. The first layer of silicon is preferably a smooth layer. In some embodiments the roughness of the first layer of silicon is within a range of up to about 0.2 nm root-mean-square deviation.

In some embodiments the first layer of silicon has a thickness of less than 50 nm. In some embodiments the thickness of the first layer of silicon is in the range of about 5 nm to about 200 nm. In some embodiments the first layer of silicon comprises isotopically purified silicon-28.

In some embodiments the first layer is deposited in a 111 orientation. In some embodiments the first layer of silicon and subsequent layers of silicon which make up the device layer are all deposited in a 111 orientation.

At block S31 method 30 applies an interfacial layer (see e.g. interfacial layer 23 in FIGS. 4A and 4B) on the first layer of silicon. The first layer of silicon may be created (e.g. formed) in step S30A or may be provided as an input (e.g. as a silicon wafer, SOI substrate or the like) in step 30B of method 30.

Interfacial layer 23 may, for example comprise a thin layer of a carbon containing material (e.g. carbon or carbon doped silicon such as silicon carbide (SIC)) on the first silicon layer. In some embodiments interfacial layer 23 has a thickness of about 10 nm.

Interfacial layer 23 may be fabricated by depositing the carbon containing material by way of a technique such as molecular beam epitaxy (MBE), chemical vapour deposition (CVD), and metal organic chemical vapour deposition (MOCVD).

Fabrication of interfacial layer 23 is an example of “delta doping”. Delta doping allows introduction of carbon into adjacent silicon layers with minimal damage to the surface and structure of the thin crystalline silicon layers. The deposited carbon layer is very thin (essentially two-dimensional). Preferably, the dopant is concentrated in one or at most two atomic layers in a crystal plane. Delta doping has been experimentally demonstrated, for example, by H.-J. Gossmann & E. F. Schubert (1993) Delta doping in silicon, Critical Reviews in Solid State and Materials Sciences, 18:1, 1-67.

Delta doping can advantageously be applied to incorporate carbon at significantly greater concentrations than would be readily achievable using other doping approaches. Delta doping takes advantage of thermodynamics, such that within each layer, the dopant atoms form a self-organized surface phase. This self-organized layer of carbon containing material within the crystal is stabilized by growing silicon (i.e. crystalline layer 25) on top of the two-dimensional dopant layer (i.e. interfacial layer 23).

In some embodiments the carbon containing material has a selected isotopic composition. For example, in some embodiments the carbon in the carbon containing material is enriched in ¹³C which has a nuclear spin. As another example, in some embodiments the carbon in the carbon-containing material has been processed to decrease or remove isotopes other than ¹²C, which does not have a nuclear spin. This allows selective preferential formation of T centres which include or do not include carbon nuclear spins. In some embodiments the carbon containing material is a mixture of isotopically enriched ¹²C and ¹³C. This may allow for forming T centres that each include a ¹³C and a ¹²C.

In some embodiments the thickness of interfacial layer 23 is less than 50 nm. In some embodiments the thickness of interfacial layer 23 is about 10 nm. In some embodiments, the thickness of the interfacial layer 23 is less than 5 nm. In a preferred embodiment the thickness of interfacial layer 23 is about 5 Angstroms.

In some embodiments the thickness of crystalline layer 25 is less than 500 nm. In some embodiments device layer 26A has a thickness in the range of about 100 nm to about 500 nm. In some embodiments device layer 26A has a thickness in the range of about 200 nm to about 350 nm (for example a thickness of about 220 nm or about 330 nm).

The material of the interfacial layer may, for example, have a carbon concentration of at least 1×10¹⁸ carbon atoms per cm³ e.g. at least 3×10¹⁸ carbon atoms per cm³ or at least 1×10¹⁹ carbon atoms per cm³. For example, graphite contains approximately 1.1×10²³ carbon atoms per cm³ and SiC contains about 5 ×10²² carbon atoms per cm³. The deposited interfacial layer has a thickness such that the interfacial layer preferably provides a density of carbon atoms of about 1×10¹¹ cm⁻² to about 1×10¹³ cm⁻² (in some embodiments about 1×10¹² cm⁻² to about 1×10¹³ cm⁻²). Block S31 may, for example, comprise depositing SiC or carbon-doped silicon by chemical vapor deposition (CVD), epitaxial CVD or molecular beam epitaxy (MBE).

It is not necessary that the concentration of carbon is equal in all parts of the interfacial layer. In some embodiments the deposition of carbon or carbon containing material to form the interfacial layer is patterned such that in some parts of the interfacial layer the carbon concentration is higher and in other parts of the interfacial layer the carbon concentration is lower. Such patterning may be applied to create a device in which the concentration of T centers varies with position in a plane of the device layer. For example, T centers may be present with a desired concentration in selected areas of the device layer and not present or present in lower concentrations in other areas of the device layer. In some embodiments patterning of the deposition of carbon containing material in block S31 is achieved by masking or applying ligands to the silicon surface on which interfacial layer 23 is being applied.

At block S33 a crystalline layer of silicon is formed on the interfacial layer. In a preferred embodiment the thickness of the crystalline layer is 10 nm or more. Block S33 may, for example, comprise depositing silicon by chemical vapor deposition (CVD) or by molecular beam epitaxy (MBE).

At block S35 depending on the growth condition and temperature, the structure output by block S33 is optionally subjected to a first annealing process. The first annealing process is a heat treatment process that allows carbon atoms to diffuse from the layer of carbon-containing material into the adjacent silicon. The carbon atoms can then occupy substitutional sites in the crystal lattice of the silicon (i.e. sites where silicon atoms are missing from the crystalline lattice). In some embodiments the first annealing process comprises heating the silicon layers to temperatures of at least 500 °C. As carbon atoms diffuse into the adjacent layers of silicon, the concentration of carbon atoms at the interface between the adjacent layers of silicon is reduced.

The first annealing process may comprise a rapid thermal annealing process in which temperature is rapidly ramped up to an annealing temperature, held at the annealing temperature for a short time and then rapidly reduced to below the annealing temperature. In some example embodiments the first annealing process comprises applying a hold temperature of about 1000 °C for a hold time of less than 30 seconds. In some embodiments the first annealing process is conducted in an oxygen-free atmosphere.

It is generally desirable that, after annealing, the carbon concentration within the silicon adjacent to the location of interfacial layer 23 is at least about 10¹⁸ or 10¹⁹ carbon atoms per cm³ in order to promote formation of T centres in the silicon. In some embodiments, after annealing, the carbon atoms that diffuse outwardly from interfacial layer 23 form a band extending to either side of the location at which the layer of carbon containing material was deposited. In this band the carbon concentration is at least about 10¹³ carbon atoms per cm³ and may be about 10¹⁸ or 10¹⁹ carbon atoms per cm³.

Block S37 introduces hydrogen into the silicon. The hydrogen may be introduced using techniques such as ion implantation or diffusion. In some embodiments the ion implantation is performed at about room temperature. In some embodiments the ion implantation has the effect of creating vacancies in the silicon lattice in which T centres may be formed and also supplying hydrogen which is required for making a T centre. In some embodiments the hydrogen is selectively supplied in some areas in the plane of the device layer and not in others (e.g., by performing the ion implantation through windows in a hard mask). Selectively implanting hydrogen in some areas of the device layer and not others is another way to control the resulting distribution of T centres in the device layer,

A second annealing process is performed in block S39. In some embodiments the second annealing process is carried out in a temperature range that is lower than that of the first annealing process (if the first annealing process has been performed). In some embodiments the second annealing process comprises heating the silicon layers to temperatures of at least 400 °C. The second annealing process may, for example, involve heating the device or at least the device layer to a temperature in the range of 400 °C to 600 °C. In some embodiments the second annealing process of block S39 and the hydrogen introduction of block S37 are performed simultaneously or at overlapping times.

In an example embodiment the second annealing process is applied for a hold time of at least 60 seconds. In an example embodiment the second annealing process is conducted in an oxygen-free atmosphere (e.g. in an inert gas atmosphere). The second annealing process facilitates hydrogen atoms bonding to carbon atoms at substitutional carbon sites and/or to interstitial carbon atoms which may migrate to substitutional carbon sites to form T centres.

After the second annealing process of block S39 spin-photon interfaces (e.g. T centres) are present in the silicon layers.

In some embodiments blocks S31 and S33 are repeated a desired number of times to add additional silicon layers having carbon containing material at interfaces between the silicon layers as indicated by loop S32. In some embodiments blocks S31 and S33 are each performed at least three times to create at least three interstitial layers of carbon containing material.

Providing a plurality of thin interfacial layers of carbon containing material separated by thin crystalline silicon layers can facilitate providing a thicker region in which, after annealing, the carbon concentration is in a good range to yield T centres or G centres. Furthermore, providing a number of closely spaced interfacial layers 23 can yield a final carbon concentration that is more uniform with depth than could be readily achieved if only one interfacial layer 23 were provided. In some embodiments silicon layers separating adjacent interfacial layers 23 are 20 nm or less in thickness. Another advantage of providing multiple interfacial layers of carbon containing material separated by thin silicon layers is that the same or even a smaller density of carbon in the interfacial layers 23 can yield higher carbon densities in the silicon crystal after annealing than would be practical to achieve if only a single interfacial layer is provided.

In some embodiments, method 30 yields a device layer that includes T centres or G centres at depths of at least 50 nm or at least 70 nm or at least 100nm below a surface of the device layer. In some embodiments a surface of the device layer is etched in block S39A. The etching may be performed to enhance a quality of the surface of the device layer and/or to adjust a depth of the T centres relative to the surface.

In some embodiments optical structures are formed in or on the device layer. The optical structures may, for example, comprise resonant structures such as photonic cavities that are tuned to enhance optical coupling to T centres in the device layer. The resonant structures may, for example, have a resonance at a photon wavelength that corresponds to an optical transition in an unpaired electron of a T centre. The optical structures may additionally comprise optical waveguides arranged to guide photons that are travelling to and from T centres. The optical structure may be created, for example, by applying silicon fabrication techniques such as selective etching to the device layer and/or by applying an optical device layer on the device layer.

FIGS. 4A and 4B are examples of intermediate structures that are ready for the first annealing process of block S35. Each of these structures has a SOI configuration. FIG. 4A is a schematic cross sectional view of a device precursor 40A according to an example embodiment of this invention. FIG. 4B is a schematic cross sectional view of a device precursor 40B according to another example embodiment. Parts of device precursors 40A and 40B which are also present in SOI structure 20 of FIG. 2 are indicated with the same references used in FIG. 2.

Device precursor 40A includes a device layer 26A. Device layer 26A comprises a plurality of sub-layers. Device layer 26A of device precursor 40A comprises a seed layer 21 fabricated on insulator layer 24, an interfacial layer 23 of a carbon containing material fabricated on seed layer 21 and a crystalline silicon layer 25 fabricated on interfacial layer 23. Interfacial layer 23 is sandwiched between seed layer 21 and crystalline silicon layer 25.

In some embodiments, device layer 26A has a thickness in the range of 100 to 500 nm. In some embodiments, luminescent centres such as T centres are concentrated at a depth within device layer 26A that is equal to one half of the thickness of device layer 26A±25%.

FIG. 4B shows another example embodiment device precursor 40B. Device precursor 40B differs from substrate 40A in that an additional first crystalline layer 27 is fabricated on seed layer 21 and then interfacial layer 23 is fabricated on first crystalline layer 27 before another crystalline layer 25 is fabricated on interfacial layer 23. The first crystalline layer 27 may thus form an intermediate silicon layer. In some embodiments the thickness of crystalline layer 25 is at least equal to the combined thickness of seed layer 21, first crystalline layer 27, and interfacial layer 23.

An advantage of providing additional first crystalline layer 27 on seed layer 21 is to increase separation between interfacial layer 23 and seed layer 21. This can reduce migration of unwanted isotopes from seed layer 21 into areas where luminescent centres such as T centres will be present. For example, if seed layer 21 comprises natural silicon (containing ²⁹Si which has a nuclear spin of ½) and it is desired to provide T centres in a body of silicon which is isotopically enriched with a silicon isotope that has zero nuclear spin (such as ²⁸Si) first crystalline layer 27 may be enriched in ²⁸Si. The presence of first crystalline layer 27 reduces the amount of unwanted isotopes from natural silicon (e.g. ²⁹Si) that can diffuse from seed layer 21 into areas in which spin-photon interfaces will be formed during the annealing step(s).

FIG. 4C shows another example embodiment device precursor 40C. Device precursor 40C differs from substrate 40A in that carbon rich silicon-based material such as SiC or carbon doped silicon is applied to seed layer 21 to form a carbon rich crystalline silicon layer 28. Seed layer 21 and carbon rich crystalline silicon layer 28 form device layer 26C. In some embodiments carbon rich crystalline silicon layer 28 comprises isotopically enriched ²⁸Si. In some embodiments carbon rich crystalline silicon layer 28 is formed with a gradient of carbon concentration such that carbon has a concentration that is lower close to seed layer 21 and increases toward the face of carbon rich crystalline silicon layer 28 that is away from seed layer 21.

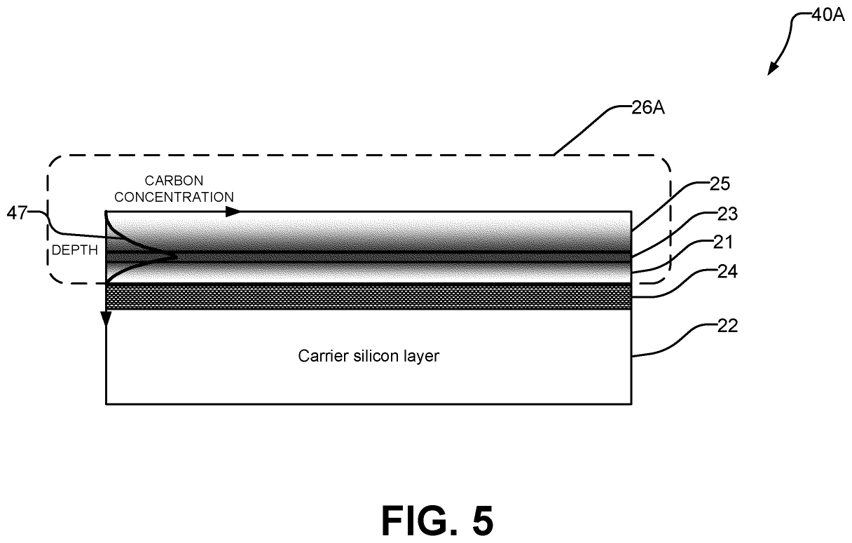

FIG. 5 is a cross sectional view of an example device 40A that shows an example carbon concentration profile 47 within modified device layer 26A.

In FIG. 5 concentration of carbon is represented by shading. Darker shading indicates a higher concentration and a lighter shading indicates a lighter concentration. Carbon concentration is the highest (shown with the darkest shade) at interfacial layer 23.

As shown in FIG. 5 after annealing, concentration of carbon outside of interfacial layer 23 is highest in parts of seed layer 21 and crystalline layer 25 that are closest to interfacial layer 23, reflecting the migration/diffusion of carbon atoms during the annealing process. A carbon profile 47 of substrate 40A shows the carbon concentration at various depths within modified device layer 26A. Carbon doping profile 47 shows carbon concentration peaking at the depth corresponding to interfacial (dopant) layer 23 and falling off with distance away from interfacial layer 23.

FIG. 6 shows another example carbon profile 57 within another example modified device layer 56 in a cross sectional view of another example device 50. Parts of device 50 which serve the same or similar functions in substrate 20 and precursor devices 40A and 40B are indicated with the same references as used in FIGS. 2-5.

Device 50 differs from precursor devices 40A and 40B in that device layer 56 of substrate 50 has multiple interfacial layers 23 that alternate with crystalline layers 25. In some embodiments interfacial layers 23 are created by deposition of two-dimensional (i.e. very thin) carbon layers. In other embodiments interfacial layers 23 are created by deposition of two-dimensional carbon doped silicon layers.

The alternate deposition of two-dimensional carbon layers (i.e. interfacial layers 23) and growth of crystalline layers 25 create a carbon-silicon superlattice structure. In a preferred embodiment, material of crystalline layers 25 is isotopically purified crystalline silicon-28.

Carbon doping profile 57 shows multiple carbon concentration peaks corresponding to multiple interfacial layers 23A-C. First and second crystalline layers 25A and 25B have the highest carbon concentration in areas near the adjacent interfacial layers 23 and the carbon concentration tapers off towards approximately the centre of crystalline layers 25A and 25B. However, because there is carbon migration/diffusion from two adjacent interfacial layers one on each side for first and second crystalline layers 25A and 25B, their lowest carbon concentration levels at approximately centre positions are still relatively high compared to areas in seed layer 21 and crystalline layer 25C that are the same distance or further away from their respective adjacent interfacial layers 23.

In contrast to the case where carbon is diffused from a single interfacial layer 23 as, for example, provided by device precursor 40A, a superlattice of alternating interfacial layers 23A-C separated by thin crystalline layers 25A-C in substrate 50 creates regions of comparatively constant carbon doping concentration in the silicon layers that are located between interfacial layers 23. Accordingly, in substrate 50, the spin-photon interfaces may be formed in layers at desired depths within modified silicon device layer 56.

In the embodiments where two-dimensional silicon carbide (SIC) layers with high carbon content are used to grow interfacial layers 23, a slightly different carbon doping profile 57 may be produced. However, such carbon doping profile 57 still has the general characteristics as shown in FIG. 5.

As discussed above, the way in which luminescent centres, such as T centres, are distributed in a device created by the methods as described herein may be controlled by one or more of:
selecting depth for one or more interfacial layers 23;
adjusting the amount of carbon containing material and/or the selection of carbon containing material included in each interfacial layer 23;
adjusting the thickness of silicon between adjacent interfacial layers 23 (in cases where there are two or more interfacial layers 23;
adjusting energy and/or dose for ion implantation of hydrogen;
controlling the amount of carbon provided in layer(s) 23 as a function of position in the plane of the device layer;
controlling the amount of hydrogen provided as a function of position in the plane of the device layer; and
adjusting temperatures and conditions of the annealing.

Where a component (e.g. a substrate, tool, device, optical element, etc.) is referred to herein, unless otherwise indicated, reference to that component (including a reference to a “means”) should be interpreted as including as equivalents of that component any component which performs the function of the described component (i.e., that is functionally equivalent), including components which are not structurally equivalent to the disclosed structure which performs the function in the illustrated exemplary embodiments of the invention.

### Interpretation of Terms

Unless the context clearly requires otherwise, throughout the description and the claims:
“comprise”, “comprising”, and the like are to be construed in an inclusive sense, as opposed to an exclusive or exhaustive sense; that is to say, in the sense of “including, but not limited to”;
“connected”, “coupled”, or any variant thereof, means any connection or coupling, either direct or indirect, between two or more elements; the coupling or connection between the elements can be physical, logical, or a combination thereof;
“herein”, “above”, “below”, and words of similar import, when used to describe this specification, shall refer to this specification as a whole, and not to any particular portions of this specification;
“or”, in reference to a list of two or more items, covers all of the following interpretations of the word: any of the items in the list, all of the items in the list, and any combination of the items in the list;
the singular forms “a”, “an”, and “the” also include the meaning of any appropriate plural forms. These terms (“a”, “an”, and “the”) mean one or more unless stated otherwise;
“and/or” is used to indicate one or both stated cases may occur, for example A and/or B includes both (A and B) and (A or B);
“approximately” when applied to a numerical value means the numerical value ±10%;
where a feature is described as being “optional” or “optionally” present or described as being present “in some embodiments” it is intended that the present disclosure encompasses embodiments where that feature is present and other embodiments where that feature is not necessarily present and other embodiments where that feature is excluded. Further, where any combination of features is described in this application this statement is intended to serve as antecedent basis for the use of exclusive terminology such as “solely,” “only” and the like in relation to the combination of features as well as the use of “negative” limitation(s)” to exclude the presence of other features; and
“first” and “second” are used for descriptive purposes and cannot be understood as indicating or implying relative importance or indicating the number of indicated technical features.

Words that indicate directions such as “vertical”, “transverse”, “horizontal”, “upward”, “downward”, “forward”, “backward”, “inward”, “outward”, “left”, “right”, “front”, “back”, “top”, “bottom”, “below”, “above”, “under”, and the like, used in this description and any accompanying claims (where present), depend on the specific orientation of the apparatus described and illustrated. The subject matter described herein may assume various alternative orientations. Accordingly, these directional terms are not strictly defined and should not be interpreted narrowly.

Where a range for a value is stated, the stated range includes all sub-ranges of the range. It is intended that the statement of a range supports the value being at an endpoint of the range as well as at any intervening value to the tenth of the unit of the lower limit of the range, as well as any subrange or sets of sub ranges of the range unless the context clearly dictates otherwise or any portion(s) of the stated range is specifically excluded. Where the stated range includes one or both endpoints of the range, ranges excluding either or both of those included endpoints are also included in the invention.

Certain numerical values described herein are preceded by “about”. In this context, “about” provides literal support for the exact numerical value that it precedes, the exact numerical value +5%, as well as all other numerical values that are near to or approximately equal to that numerical value. Unless otherwise indicated a particular numerical value is included in “about” a specifically recited numerical value where the particular numerical value provides the substantial equivalent of the specifically recited numerical value in the context in which the specifically recited numerical value is presented. For example, a statement that something has the numerical value of “about 10” is to be interpreted as: the set of statements:
in some embodiments the numerical value is 10;
in some embodiments the numerical value is in the range of 9.5 to 10.5;
   and if from the context the person of ordinary skill in the art would understand that values within a certain range are substantially equivalent to 10 because the values with the range would be understood to provide substantially the same result as the value 10 then “about 10” also includes:
in some embodiments the numerical value is in the range of C to D where C and D are respectively lower and upper endpoints of the range that encompasses all of those values that provide a substantial equivalent to the value 10

Specific examples of systems, methods and apparatus have been described herein for purposes of illustration. These are only examples. The technology provided herein can be applied to systems other than the example systems described above. Many alterations, modifications, additions, omissions, and permutations are possible within the practice of this invention. This invention includes variations on described embodiments that would be apparent to the skilled addressee, including variations obtained by: replacing features, elements and/or acts with equivalent features, elements and/or acts; mixing and matching of features, elements and/or acts from different embodiments; combining features, elements and/or acts from embodiments as described herein with features, elements and/or acts of other technology; and/or omitting combining features, elements and/or acts from described embodiments.

As will be apparent to those of skill in the art upon reading this disclosure, each of the individual embodiments described and illustrated herein has discrete components and features which may be readily separated from or combined with the features of any other described embodiment(s) without departing from the scope of the present invention.

Any aspects described above in reference to apparatus may also apply to methods and vice versa.

Any recited method can be carried out in the order of events recited or in any other order which is logically possible. For example, while processes or blocks are presented in a given order, alternative examples may perform routines having steps, or employ systems having blocks, in a different order, and some processes or blocks may be deleted, moved, added, subdivided, combined, and/or modified to provide alternative or subcombinations. Each of these processes or blocks may be implemented in a variety of different ways. Also, while processes or blocks are at times shown as being performed in series, these processes or blocks may instead be performed in parallel, simultaneously or at different times.

Various features are described herein as being present in “some embodiments”. Such features are not mandatory and may not be present in all embodiments. Embodiments of the invention may include zero, any one or any combination of two or more of such features. All possible combinations of such features are contemplated by this disclosure even where such features are shown in different drawings and/or described in different sections or paragraphs. This is limited only to the extent that certain ones of such features are incompatible with other ones of such features in the sense that it would be impossible for a person of ordinary skill in the art to construct a practical embodiment that combines such incompatible features. Consequently, the description that “some embodiments” possess feature A and “some embodiments” possess feature B should be interpreted as an express indication that the inventors also contemplate embodiments which combine features A and B (unless the description states otherwise or features A and B are fundamentally incompatible). This is the case even if features A and B are illustrated in different drawings and/or mentioned in different paragraphs, sections or sentences.

It is therefore intended that the following appended claims and claims hereafter introduced are interpreted to include all such modifications, permutations, additions, omissions, and sub-combinations as may reasonably be inferred. The scope of the claims should not be limited by the preferred embodiments set forth in the examples, but should be given the broadest interpretation consistent with the description as a whole.

1. A method for making a device that includes luminescent centres, the method comprising the steps of:
(a) fabricating a device layer on a substrate by:
(i) forming, on a first silicon layer formed on the substrate, a first interfacial layer of a carbon containing material; and,
(ii) forming a second silicon layer on the first interfacial layer;
(b) introducing hydrogen atoms into the device layer; and,
(c) annealing the device layer to cause the carbon atoms and the hydrogen atoms to form luminescent centres within the device layer.

2. The method according to claim 1 comprising causing carbon atoms to diffuse into the first and second silicon layers from the interfacial layer by applying a first annealing process after forming the second silicon layer.

3.-4. (canceled)

5. The method according to claim 1 comprising:
forming a plurality of alternating interfacial layers and silicon layers by alternately applying step (a)(i) to each successive silicon layer and step (a)(ii) to each successive interfacial layer before step (b).

6.-13. (canceled)

14. The method according to claim 1, wherein, a concentration of the luminescent centres is greatest at a depth corresponding to the interfacial layer.

23. The method according to claim 1, comprising forming an intermediate silicon layer on the first silicon layer prior to forming the first interfacial layer.

24.-27. (canceled)

28. A precursor device comprising:
a substrate comprising a carrier silicon layer and an insulator layer;
a device layer supported on the substrate, the device layer comprising:
a first silicon layer adjacent to the insulator layer of the substrate;
an interfacial layer of carbon containing material deposited on the first silicon layer; and
a second silicon layer deposited on the interfacial layer.

29. The precursor device according to claim 28 comprising a second interfacial layer of carbon containing material deposited on the second silicon layer and a third silicon layer deposited on the second interfacial layer.

30. The precursor device according to claim 29 comprising a third interfacial layer of carbon containing material deposited on the third silicon layer and a fourth silicon layer deposited on the third interfacial layer.

31. The precursor device according claim 28 wherein at least one of the silicon layers comprises isotopically purified silicon-28.

32. The precursor device according to claim 28 wherein the carbon containing material is silicon carbide, carbon doped silicon. or elemental carbon.

33.-35. (canceled)

36. The precursor device according to claim 28 wherein the carbon containing material is isotopically enriched in ¹³C.

37.-41. (canceled)

42. The precursor device according to claim 28 wherein the interfacial layer has a carbon concentration of at least 1×10¹⁸ atoms cm⁻³.

43. The precursor device according to claim 28 wherein the interfacial layer has a density of about 1×10¹¹ atoms cm⁻² to about 1×10¹³ atoms cm⁻².

44. The precursor device according to claim 28 comprising an intermediate silicon layer between the first silicon layer and the interfacial layer.

45. The precursor device according to claim 44 wherein a thickness of the second silicon layer is at least equal to a combined thickness of the first silicon layer, the intermediate silicon layer and the interfacial layer.

46. (canceled)

47. A device comprising:
a substrate;
a device layer supported on the substrate;
a plurality of luminescent centres localized within the device layer and concentrated within a first depth range that is equal to one half of the thickness of the device layer ±25%,
wherein an average concentration of the luminescent centres within the first depth range is at least five times greater than an average concentration of the luminescent centres in a second depth range that extends from an outer surface of the device layer by a distance equal to 10% of the thickness of the device layer.

48. The device according to claim 47 wherein the luminescent centres are T centres.

49. The device according to claim 48 further comprising an optical layer on the device layer wherein the optical layer comprises a plurality of optical resonators which have resonances at wavelengths corresponding to optical transitions of the T centres.

50. The precursor device according to claim 28, wherein the interfacial layer has a thickness not exceeding 2 nm.

51. The device according to claim 47, wherein the device layer comprises crystalline silicon and has a thickness of 500 nm or less.
